(19) United States
(12) Patent Application Publication
(10) Pub. No.: US 2010/0181652 A1
(43) Pub. Date: Jul. 22, 2010

(54) SYSTEMS AND METHODS FOR STICTION REDUCTION IN MEMS DEVICES

(75) Inventors: Chris Milne, Issaquah, WA (US); Jeff A. Ridley, Shorewood, MN (US); Galen Magendanz, Issaquah, WA (US); Marcos Daniel Ruiz, Redmond, WA (US)

Correspondence Address: HONEYWELL/BLG;Patent Services, 101 Columbia Road, PO Box 2245, Morristown, NJ, 07962-2245, US

(73) Assignee: Honeywell International Inc., Morristown, NJ (US)

(21) Appl. No.: 12/355,506

(22) Filed: Jan. 16, 2009

(51) Int. Cl. H01L 23/44; H01L 21/02

(52) U.S. Cl. 257/629; 438/127; 257/E23.002; 257/E23.194; 257/E21.002

(57) ABSTRACT

Systems and methods for reducing stiction between elements of a microelectromechanical systems (MEMS) device during anodic bonding. The MEMS device includes a substrate cover with an optional conductor on its interior surface and the cover is anchored to a first portion of a sensing element. The MEMS device further includes a second portion of the sensing element separated from the substrate cover with a space and an antistiction element disposed between the second portion and cover. The antistiction element can be formed of a material type with high electrostatic resistance, to prevent stiction between MEMS device elements during anodic bonding.

### BACKGROUND OF THE INVENTION

Certain microelectromechanical (MEMS) sensor devices include both an upper and a lower covering with a space-gap interposed therebetween. This space gap can contain a substrate wafer that acts as a sensing or actuating mechanism for the MEMS device. The gap is formed between recessed areas at the periphery of the upper and lower coverings, and the substrate wafer can be hermetically sealed between the two coverings in a very sensitive anodic bonding process.

During an anodic bonding process, a secured substrate wafer is first bonded to the lower covering at raised contact regions at the covering's periphery edge. This process can involve the application of high temperatures and an electric potential of several hundred to a few thousand volts. Next, wafer elements that constrain device movement in a plane orthogonal to the covering are removed and the upper covering is similarly bonded to both the unsecured substrate wafer and the lower covering at raised contact regions at the covering's periphery edges.

The physical bonding occurs as a result of a current that flows between the substrate wafer and the coverings at their points of contact. The strength of this bond is proportional to the magnitude of electric potential applied during the bonding process.

Unfortunately, when too high an electric potential is applied across a covering, an undesirable electrostatic effect occurs, which is commonly known as stiction. For example, during the bonding of the upper covering, upwardly compliant component on the substrate wafer can adhere to a conductor component on the bottom surface of the upper covering. This stiction can render a MEMS device unusable.

Therefore, there remains a need for an effective deterrent to stiction between sensitive MEMS device components in the anodic bonding process. It would be advantageous if this deterrent could increase the voltage threshold point at which stiction occurs, thereby increasing MEMS device production yield, while at the same time creating a more robust MEMS device.

### SUMMARY OF THE INVENTION

The present invention provides systems and methods for preventing stiction between MEMS device components in an anodic bonding process. In accordance with one aspect of the present invention a MEMS device includes a substrate cover with an interior surface, anchored to a first portion of a sensing or actuating element, an optional conductor residing on the interior surface of the substrate cover, a second portion of the sensing element separated from the substrate cover with a space, and an antistiction element disposed between the second portion of the sensing element and the cover to prevent stiction during anodic bonding.

In accordance with further aspects of the invention, the conductor, the cover or the second portion of the sensing element can include the antistiction element.

In accordance with another aspect of the invention, the conductor or cover can include bumples (small volumes that protrude from the surface) or strips that reduce a contact surface area between the second portion of the sensing element and the conductor.

In accordance with other aspects of the invention, the antistiction element can be formed from Titanium Nitride, Titanium Tungsten, Tungsten, Ruthenium, Rhodium, or Iridium or other similar materials.

In accordance with still further aspects of the invention, the first portion of the sensing element can be bonded to the periphery edge of the substrate cover with application of an electric potential.

In accordance with still further aspects of the invention, the applied electric potential is a voltage greater than 200 volts.

In yet further aspects of the invention, a method for preventing stiction between MEMS device components in an anodic bonding process includes bonding a first substrate cover to a first portion of a sensing or actuating element, disposing an antistiction element between a second portion of the sensing or actuating element and an interior surface of the second substrate cover, and bonding the first portion of the sensing or actuating element to a second substrate cover, such that the antistiction element prevents stiction of the second portion of the sensing element, when an electric potential is applied.

As will be readily appreciated from the foregoing summary, the invention provides means for improving the production yield of sensitive MEMS devices by deterring stiction between device components during anodic bonding.

### BRIEF DESCRIPTION OF THE DRAWINGS

Preferred and alternative embodiments of the present invention are described in detail below with reference to the following drawings:

FIG. 1 is a cross-sectional view of a MEMS device in accordance with an embodiment of the present invention;

FIG. 2 is a top perspective view of a MEMS device with its upper covering removed in accordance with an embodiment of the present invention;

FIG. 3 is a top perspective view of a MEMS device with its upper covering removed in accordance with another embodiment of the present invention; and

FIG. 4 is a cross-sectional view of a MEMS device in accordance with an embodiment of the present invention.

### DETAILED DESCRIPTION OF THE INVENTION

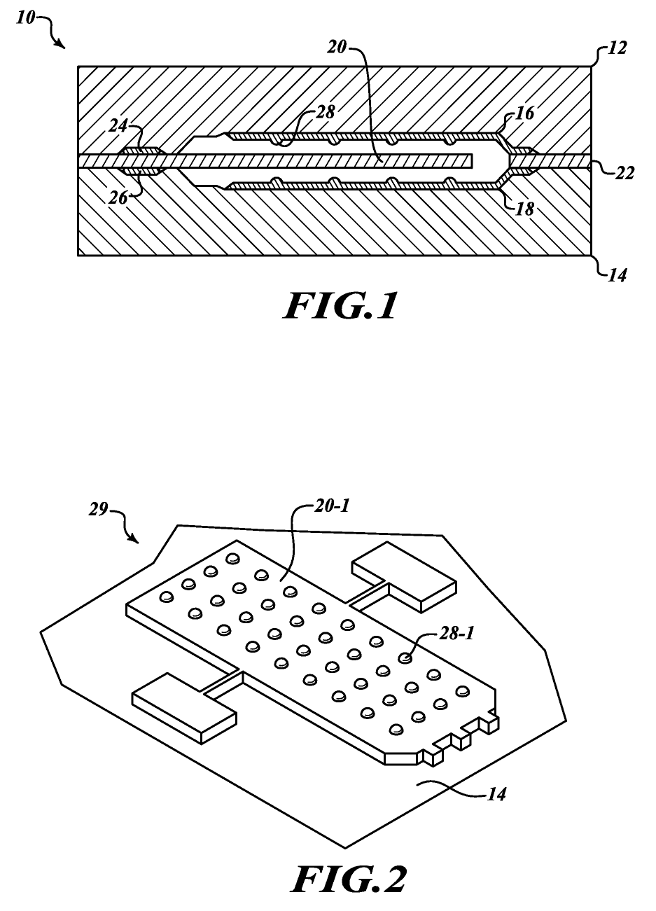

The present invention provides systems and methods for reducing stiction between elements of a microelectromechanical systems (MEMS) sensor or actuator device during anodic bonding. FIG. 1 illustrates a MEMS device 10 in accordance with an embodiment of the present invention. The components of the MEMS device 10 include: an upper substrate cover 12, a lower substrate cover 14, an upper conductor 16, a lower conductor 18, a sensing or actuating element 20 in a device layer 22, an upper anchor 24, a lower anchor 26, and one or more antistiction elements 28.

During fabrication of the MEMS device 10, the lower substrate cover 14 can be configured to include a lower conductor 18 that resides on an interior surface of the lower substrate cover 14. In an embodiment, the lower conductor 18 includes the antistiction elements 28. In accordance with a first bonding process, a single wafer substrate that includes the sensing or actuating element 20 in the device layer 22 are bonded to the lower substrate cover 14 utilizing the lower anchor 26 and an anchor portion of the lower conductor 18 (this would be thermal compression bonding) as bonding agents. The first bonding process can include application of an electric potential of sufficient magnitude to induce a bonding current amongst the lower substrate cover 14, including the lower anchor 26, and the exterior portions of the single wafer substrate that include the sensing or actuating element 20 and the device layer 22.

The device layer 22 bonded to the lower substrate cover 14 and to the anchor 26 in the first bonding process can then be segmented through an etching process (or other type of removal process) that is irreversible. The segmented portions include the sensing or actuating element 20 and other components. In an embodiment, the sensing or actuating element 20 includes a first portion and a second portion. In this embodiment, the etching that separates the single wafer substrate, occurs after the first bonding process. Therefore, there is no chance of electrically induced stiction between device elements during bonding, as the MEMS device elements are each attached with no freestanding portions.

The next step of the fabrication process can include a second bonding process where the first portion of the sensing or actuating element 20 bonded to the upper substrate cover 12 utilizing the upper anchor 24 as a bonding agent (see comments above). In one embodiment, the upper conductor 16 resides on the interior surface of the upper substrate cover 12, and the upper conductor 16 includes the antistiction elements 28. The antistiction elements 28 are designed to prevent stiction between the second portion of the sensing or actuating element 20 and the upper conductor 16, when an electric potential is applied between these two features during the second bonding process.

The MEMS device elements being bonded during the second bonding process can be bonded together through application of an electric potential of several hundred to a few thousand volts. Both the magnitude of a bonding current induced between MEMS device elements being bonded and the strength of the ensuing physical bond are proportionate to the magnitude of the electric potential applied across the upper substrate cover 12 during the second bonding process. The antistiction elements 28 are designed to prevent stiction as the second portion of the sensing or actuating element 20 deflects (arcing implies an electrical arc, in this case it is a physical deflection) towards the upper substrate cover 12 during application of a predetermined electric potential in the second bonding process. In one embodiment, the antistiction elements 28 are designed to resist stiction with the application of electric potential greater than 200 volts during the second bonding process.

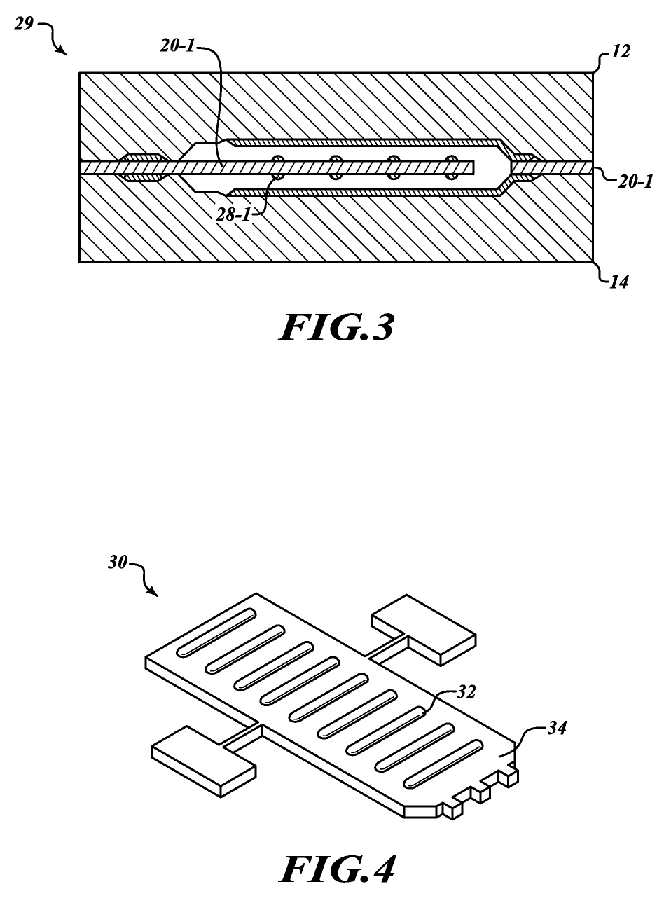

As shown in FIGS. 2 and 3, a MEMS device 29 includes a sensing or actuating element 20-1 that includes one or more bumple elements 28-1. The bumple elements 28-1 reduce a contact surface area between a deflected portion of the sensing or actuating element 20-1 and upper conductor cover 12 during the second anodic bonding process. The bumple elements 28-1 are located on one or both sides of the sensing or actuating element 20-1. The bumples or strips can be formed using one of several methods: 1) using photolithography and a subsequent “lift-off” process; 2) using an aperture or shadow mask.

As shown in FIG. 4, a MEMS device 30 includes a sensing or actuating element 34 that includes strip elements 32. The strip elements 32 reside on the surface of the sense or actuating element 34.

In an embodiment, a MEMS device component's material type can be fabricated from a plurality of materials having specialized conductive or insulating properties. In one embodiment, the antistiction elements (28-1 and 32 of FIGS. 1-4) are formed from Titanium Nitride, Titanium Tungsten, Tungsten, Ruthenium, Rhodium, or Iridium. The antistiction elements 28 are formed of a conductive material such as Gold, but may be formed on a non-conductive material. In another embodiment, the upper and lower covers (12 and 14) are formed of a glass substrate and the sensing or actuating elements (20, 20-1 and 34) are formed of a Silicon substrate.

In an embodiment, the bumples or strips are coated to include multiple layers of materials, such that the outer layer is more resistant to stiction induced bonding with the substrate (e.g., Silicon) of the sensing or actuating elements (20, 20-1 and 34). One Example of an outer layer that is particularly resistant to electrostatic bonding with Silicon is Graphite. In another embodiment, a sensing or actuating element is hermetically sealed between the covers of the MEMS device during fabrication.

Example dimensions for the bumbles are ˜5 μm×5 μm×0.1 μm (height) and larger. Strips would be ˜5 μm wide×several hundred microns long×˜0.1 μm (height).

While various embodiments of the invention have been illustrated and described, many changes can be made without departing from the spirit and scope of the present invention. Accordingly, the scope of the invention is not limited by the disclosure of the preferred embodiment. Instead, the invention should be determined by reference to the claims that follow.

The embodiments of the invention in which an exclusive property or privilege is claimed are defined as follows:

1. A microelectromechanical systems (MEMS) device comprising:
an element configured to perform one of sensing or actuating, the element having a first portion and a second portion,
a substrate cover with an interior surface, the substrate cover anchored to the first portion; and
an antistiction element located between the second portion and the substrate cover, wherein the antistiction element prevents stiction during anodic bonding,
wherein a space separates the second portion from the substrate cover.

2. The device of claim 1, wherein the antistiction element is attached to the interior surface.

3. The device of claim 2, wherein the antistiction element comprises bumples that reduce a contact surface area between the second portion of the element and the interior surface.

4. The device of claim 2, wherein the antistiction element comprises strips that reduce a contact surface area between the second portion of the element and the interior surface.

5. The device of claim 1, wherein the second portion of the element comprises the antistiction element.

6. The device of claim 5, wherein the antistiction element is formed from one of Titanium Nitride, Titanium Tungsten, Tungsten, Ruthenium, Rhodium or Iridium.

7. The device of claim 5, wherein the antistiction element comprises one of bumples or strips.

8. The device of claim 1, wherein the first and second portions of the element are formed of silicon.

9. The device of claim 1, wherein the first portion of the element is bonded to a peripheral edge of the substrate cover with application of an electric potential.

10. The device of claim 9, wherein the applied electric potential is a voltage greater than 200 volts.

11. The device of claim 1, further comprising a conductor residing on the interior surface of the substrate cover, wherein the antistiction element is attached to the conductor.

12. The device of claim 11, wherein the antistiction element comprises at least one of bumples or strips that reduce a contact surface area between the second portion of the element and the conductor.

13. A method for preventing stiction between microelectromechanical systems (MEMS) device components in an anodic bonding process, the method comprising:
bonding a first substrate cover to a first portion of a element configured to perform one of sensing or actuating;
disposing an antistiction element between a second portion of the element and an interior surface of the first substrate cover; and
bonding the first portion of the element to a second substrate cover, such that the antistiction element prevents stiction of the second portion of the element, when an electric potential is applied.

14. The method of claim 13, wherein the interior surface comprises the antistiction element.

15. The method of claim 14, wherein the antistiction element comprises bumples that reduce a contact surface area between the second portion of the sensing element and the interior surface.

16. The method of claim 14, wherein the antistiction element comprises strips that reduce a contact surface area between the second portion of the sensing element and the interior surface.

17. The method of claim 13, wherein the antistiction element is formed of at least one of Titanium Nitride, Titanium Tungsten, Tungsten, Ruthenium, Rhodium or Iridium.

18. The method of claim 13, wherein the second portion comprises the antistiction element.

19. The method of claim 18, wherein the antistiction element comprises one of bumples or strips.

20. The method of claim 13, wherein the electric potential is a voltage greater than 200 volts.
